(19) United States
(12) Patent Application Publication
(10) Pub. No.: US 2012/0060889 A1
(43) Pub. Date: Mar. 15, 2012

(54) Thermoelectric modules and assemblies with stress reducing structure

(75) Inventors: Robert W. Otey, Litchfield, NH (US); David A. Kaminski, Dunbarton, NH (US)

(73) Assignee: FERROTEC (USA) CORPORATION, Bedford, NH (US)

(21) Appl. No.: 13/231,331

(22) Filed: Sep. 13, 2011

Related U.S. Application Data
(60) Provisional application No. 61/382,296, filed on Sep. 13, 2010.

(51) Int. Cl. H01L 35/32; H01L 31/18

(52) U.S. Cl. 136/225; 438/54; 136/201; 257/E31.001

(57) ABSTRACT

A thermoelectric module capable of minimizing thermally and physically induced stress includes a pair of substrates having a plurality of electrically conductive contacts disposed on opposing faces, a plurality of P-type and N-type thermoelectric elements interposed between the pair of substrates forming a thermoelectric element circuit, and one or more of a stress minimizing structural element interposed between the pair of substrates where the stress minimizing structural element has a first surface fixed to one of the pair of substrates and a second surface fixed to the other of the pair of substrates in locations between the pair of substrates that minimize the effects of physical and thermal stresses on the plurality of P-type and N-type thermoelectric elements.

This application claims the benefit of U.S. Provisional Patent Application No. 61/382,296, filed Sep. 13, 2010.

### BACKGROUND OF THE INVENTION

1. Field of the Invention

The present invention relates generally to thermoelectric devices. Particularly, the present invention relates to thermoelectric devices and a method of fabricating the same.

2. Description of the Prior Art

Thermoelectric cooling was first discovered by Jean-Charles-Athanase Peltier in 1834, when he observed that a current flowing through a junction between two dissimilar conductors induced heating or cooling at the junction, depending on the direction of current flow. This is called the Peltier effect. Practical use of thermoelectrics did not occur until the early 1960s with the development of semiconductor thermocouple materials, which were found to produce the strongest thermoelectric effect. Most thermoelectric materials today comprise a crystalline alloy of bismuth, tellurium, selenium, and antimony.

Thermoelectric devices are solid-state devices that serve as heat pumps. They follow the laws of thermodynamics in the same manner as mechanical heat pumps, refrigerators, or any other apparatus used to transfer heat energy. The principal difference is that thermoelectric devices function with solid state electrical components as compared to more traditional mechanical/fluid heating and cooling components.

The circuit for a simple thermoelectric device generally includes two dissimilar materials such as N-type and P-type thermoelectric semiconductor elements. The thermoelectric elements are typically arranged in an alternating N-type element and P-type element configuration. In many thermoelectric devices, semiconductor materials with dissimilar characteristics are connected electrically in series and thermally in parallel. The Peltier effect occurs when the voltage is applied to the N-type elements and the P-type elements resulting in current flow through the serial electrical connection and heat transfer across the N-type and P-type elements in the parallel thermal connection.

Typical construction of a thermoelectric module consists of electrically connecting a matrix of thermoelectric elements (dice) between a pair of electrically insulating substrates. The operation of the device creates both a hot-side substrate and a cool-side substrate. The module is typically placed between a load and a sink such as liquid plates, surface plates, or convection heat sinks. The most common type of thermoelectric element is composed of a bismuth-tellurium (Bi₂Te₃) alloy.

A thermoelectric device typically requires DC power in order to produce a net current flow through the thermoelectric elements in one direction. The direction of the current flow determines the direction of heat transfer across the thermoelectric elements. The direction of net, non-zero current flow through the thermoelectric elements determines the function of the thermoelectric device as either a cooler or heater.

Thermoelectric modules are available with rigid substrates such as, for example, substrates made of alumina (96%) or thin film and/or flexible substrates. Rigid substrates typically range in thickness from about 0.010 inches (0.25 mm) to about 0.040 inches (1.0 mm). A description of conventional thermoelectric modules and technology is also provided in the CRC Handbook of Thermoelectrics and Thermoelectric Refrigeration by H. J. Goldsmid. A disadvantage of using a ceramic substrate is the brittleness of the ceramic and the thermal stresses that occur at the junction of the substrate and the thermoelectric semiconductor chips. Other disadvantages of using rigid substrates are that the substrates must be thick enough to withstand cracking. The thicker the module, the heavier the thermoelectric module becomes. Also, material costs for the thicker substrates are higher. In addition, the use of ceramic substrates limits the size and shape of thermoelectric modules.

Also, the rigidity of the ceramic substrate and the thermal cycling of a thermoelectric module where the heating side of the module is trying to expand while the cooling side of the module is trying to contract cause a “Potato Chip Effect.” This effect puts stresses on the thermoelectric chips or dice and results in the eventual failure at the junctures between different mediums. These stresses increase as the module size increases. Furthermore, current thermoelectric module technology limits the available applications where these devices can be used. For instance, current thermoelectric module technology is not practical in applications having irregular and non-flat surfaces. One advantage of the rigid substrate modules is that they are resistant to mechanical or manual handling stresses due to the fact that the substrates are rigid.

Flexible substrates in thermoelectric modules overcome the many disadvantages found with thermoelectric modules using rigid substrates and have many advantages over thermoelectric modules with rigid substrates. Flexible substrates allow relatively large thermoelectric modules to be made that are not practical using rigid substrates. Flexible substrates also provide the ability to make thermoelectric modules that follow the contour of a shaped surface, thus making thermoelectric modules a viable alternative for applications that have irregular and/or non-flat surfaces. Use of a thin, flexible film substrate in a thermoelectric module reduces the overall weight of a thermoelectric module and reduces manufacturing costs. Because thermoelectric modules are generally used in applications that turn the thermoelectric module on and off, the use of a flexible substrate increases cycling life of the thermoelectric module. The flexibility of the substrate reduces the overall stresses caused by thermal cycling.

Although there are many advantages of making thermoelectric modules using flexible substrates, there remain some problems in both ceramic-based substrates and flexible substrates. Thermally and/or physically induced stress can cause premature failure in all thermoelectric modules but thermally-induced stress to a lesser degree in modules using flexible substrates. Physically, this occurs because the very property of being thin and flexible also makes it vulnerable to mechanical forces when the thermoelectric module is assembled into an assembly having heat conducting structure such as, for example, heat exchanger fins attached to the exposed sides of the flexible substrates. The additional weight and mass of the heat conducting structure may cause induced and localized stresses in the thermoelectric module causing premature failure.

Therefore, what is needed is a thermoelectric module that minimizes the effect of thermally and/or physically induced stress.

### SUMMARY OF THE INVENTION

Thermoelectric modules consist of an array of thermoelectric elements or thermoelectric components made from thermoelectric materials. These thermoelectric elements are usually rectangular in shape though they can be cylindrical and consist mostly of thermoelectric material. Typically, two of the six sides, located opposite each other, are further bonded to material that acts as a barrier to material elements that may adversely affect performance of the thermoelectric material as the adverse material diffuses into the thermoelectric material. In the case of a cylindrical thermoelectric element, the two flat ends generally receive the additional protective material.

The diffusion barrier also acts as a layer to which solder can wet, as materials such as Bismuth Telluride or Antimony telluride do not wet well with typical solder alloys. This allows the thermoelectric elements to be placed into an array and soldered into a circuit.

As a thermoelectric module is assembled or in operation, there are conditions that are experienced which can cause stress to be applied to the thermoelectric element and the layers bonded to it. This includes physical force from handling and manipulation during assembly as well as thermally induced stresses during operation when one side of the thermoelectric element array becomes hot and the other cold resulting in expansion on one side and contraction on the other and the associated stress from the difference. This stress is dependent upon loading conditions and the temperature differential and the thermal coefficient of expansion (TCE) of the various materials.

One method to counter module damage from these mechanical stress forces includes potting the sides of the thermoelectric modules by filling the gap between the substrates with epoxy or other materials. The potting material limits movement of the components (the thermoelectric elements, etc.). One disadvantage of using a potting material is the inclusion of an additional step in the manufacturing process that adds time and expense to the module. Another disadvantage is the potting material must be mixed in the proper proportions to avoid forming a cured material with a film of uncured potting component in and around the thermoelectric elements that could lead to short circuits.

The present invention includes the use of structural elements such as posts, rails and other shapes made of distinctly different materials from the material of the thermoelectric elements. The structural elements are added to the usual array of thermoelectric elements to alleviate the physically and thermally induced stresses by reducing the stress-inducing forces experienced by the thermoelectric elements. There are material properties that make these structural elements preferred for use as a structural element. A lesser desirable alternative would be using very large thermoelectric elements that are more able to withstand imposed stresses.

The structural elements are positioned between the two substrates of the thermoelectric module in much the same way as the thermoelectric elements are positioned. These structural elements may be soldered, melted, adhered, or bonded into position. The preferred method is to solder the structural elements into position. Where soldering is preferred, the material used for the structural elements needs to be wetable by solder and to withstand the reflow temperature of the solder to be used. One such material is a laminate consisting of two layers of copper with a filler material in between which may be epoxy, plastic, ceramic, or a composite such as a glass filled thermoplastic.

In addition, the structural element material preferably has a low thermal conductivity in order to prevent thermal shorting. Bismuth telluride used for the thermoelectric element has a thermal conductivity of approximately 1.5 W/m° K. The structural element material should possess a thermal conductivity no greater than the thermal conductivity of the thermoelectric element and preferably less than the thermal conductivity of the thermoelectric element.

Furthermore, the material should be electrically insulating, possess a low coefficient of thermal expansion, easily fabricated into forms approximately the same height and size as the thermoelectric elements, remain strong during operating conditions and also possess a bond strength greater than that between the thermoelectric elements and their respective diffusion barriers. A laminate of copper and glass filled polyimide meets all of these criteria as copper is easily wetted by solder, polyimide has a low thermal conductivity, it is electrically insulating, has a glass transition temperature greater than 110° C., can be processed at lead free solder temperatures, and is easily machined or fabricated to the desired form.

Some of these properties may be ignored if the resulting degradation of performance of the module is acceptable. For instance, a structural element of highly thermally conductive material may be used but the thermal conductivity would allow additional heat to transfer back across the module in the wrong direction. Or, if a structural element of electrically conductive material were used, the need for mounting pads isolated from the circuit would be required.

These structural elements may be placed in strategic positions to reduce the stresses experienced by the module. Common positions for the location of these would be in areas where leads are attached due to the resulting lever effect of the attached leads to the module or at positions where stresses from thermal coefficients of expansion are greatest. For example, the structural elements may be used where power leads are attached to the module or at the furthest corners of a module located away from any neutral deflection and stress axis.

The structural elements may be incorporated into the matrix of thermoelectric elements by replacing selected or predetermined thermoelectric elements with structural elements or remain outside of the array of thermoelectric elements such as placing the structural elements along the side of the outermost columns of thermoelectric elements in the array. Further, even when incorporated inside the array of thermoelectric elements, they can be positioned into the circuit if they meet certain criteria or possess their own areas for attachment.

The present invention achieves these and other objectives by providing a a thermoelectric module and method of making a thermoelectric module capable of minimizing thermally and physically induced stress in any module and in particular those built with thin layer/flexible substrates.

In one embodiment, the thermoelectric module includes having a plurality of electrically conductive contacts disposed on opposing faces of the substrates, a plurality of P-type and N-type thermoelectric elements interposed between the pair of substrates, each of the plurality of conductive contacts connecting adjacent P-type and N-type thermoelectric elements to each other in series forming a thermoelectric element circuit, and an electrically non-conductive stress minimizing structural element interposed between the pair of substrates where the stress minimizing structural element has a first surface connected to one of the pair of substrates and a second surface connected to the other of the pair of substrates in locations between the pair of substrates that minimize the effects of physical and thermal stresses on the plurality of P-type and N-type thermoelectric elements.

In another embodiment of the present invention, the thermoelectric module includes having a plurality of electrically conductive contacts disposed on opposing faces of the substrates where at least one of the substrates is a flexible substrate, a plurality of P-type and N-type thermoelectric elements interposed between the pair of substrates, each of the plurality of conductive contacts connecting adjacent P-type and N-type thermoelectric elements to each other in series forming a thermoelectric element circuit, and an electrically non-conductive stress minimizing structural element interposed between the pair of substrates where the stress minimizing structural element has a first surface connected to one of the pair of substrates and a second surface connected to the other of the pair of substrates in locations between the pair of substrates that minimize the effects of physical and thermal stresses on the plurality of P-type and N-type thermoelectric elements.

In another embodiment of the present invention, stress minimizing structural element(s) is (are) incorporated into the thermoelectric element circuit in a predefined location electrically separate from the thermoelectric circuit.

In still another embodiment of the present invention, stress minimizing structural element (s) is (are) incorporated into the thermoelectric element circuit where a predefined thermoelectric element in the thermoelectric element circuit is replaced by the stress minimizing structural element or is incorporated outside of the thermoelectric element circuit. In the case where the stress minimizing structural element is incorporated into the thermoelectric element circuit replacing a thermoelectric element, the structural element must be electrically conductive. This may be accomplished in various ways including, but not limited to, coating the outer surface of the structural element with an electrically conductive coating, coating at least one side of the structural element with an electrically conductive coating such that the electrically conductive coating provides electrical continuity to the thermoelectric element circuit between the opposed substrates, disposing an electrically conductive pathway through the length of the structural element so that it provides electrical continuity to the thermoelectric element circuit between the substrates, and the like.

In a further embodiment of the present invention, the stress minimizing structural element is made of a material selected from the group consisting of epoxy, plastic, ceramic, metal, and composite. The composite is preferably a glass-filled thermoplastic and, more preferably, it is a glass-filled polyimide.

In still another embodiment of the present invention, the stress minimizing structural element is a laminate. In one example, the laminate includes a structural element body having a metal coating on opposite ends of the structural element body or opposite longitudinal sides of the structural element body. The metal coating is preferably copper.

In yet another embodiment of the present invention, the stress minimizing structural element is made of material having at least one characteristic selected from the group consisting of low thermal conductivity on a thermal conductivity scale, electrically insulating, bond strength greater than the bond strength between one of the plurality of thermoelectric elements and a barrier layer disposed on opposite ends of the thermoelectric element, and a thermal conductivity equal to or less than the thermal conductivity of one of the plurality of thermoelectric elements.

In another embodiment of the present invention, the stress minimizing structural element is attached to each of the pair of substrates by being soldered, melted or adhesively fixed into position.

In a further embodiment of the present invention, the stress minimizing structural element is either attached to the dielectric substrate surfaces of the pair of substrates or to the electrically conductive pads disposed on the dielectric substrate surfaces.

In another embodiment of the present invention, there is disclosed a method of making a thermoelectric module capable of minimizing thermally and physically induced stress. The method includes obtaining a pair of substrates having a plurality of electrically conductive contacts disposed on opposing faces, electrically connecting a plurality of P-type and N-type thermoelectric elements between opposing sides of the pair of substrates having the plurality of electrical contacts/pads where each of the plurality of electrical contacts connects adjacent P-type and N-type elements to each other in series forming a thermoelectric element circuit, and securing one or more of a stress minimizing structural element between the pair of substrates where the stress minimizing structural element has a first surface connected to one of the pair of substrates and a second surface connected to the other of the pair of substrates in locations between the pair of substrates that minimize the effects of physical and thermal stresses on the plurality of P-type and N-type thermoelectric elements.

In another embodiment of the method of the present invention, the securing step includes incorporating the stress minimizing structural element into the thermoelectric element circuit where a predefined thermoelectric element in the thermoelectric element circuit is replaced by the stress minimizing structural element. In this case as explained above, the stress minimizing structural element must be electrically conductive.

In a further embodiment of the method, the securing step includes incorporating the stress minimizing structural element outside of the thermoelectric element circuit.

In another embodiment, the method includes forming the stress minimizing structural element from a material selected from the group consisting of epoxy, plastic, ceramic, and composite metal.

In still another embodiment, the method includes forming the stress minimizing structural element from a material having at least one characteristic selected from the group consisting of low thermal conductivity on a thermal conductivity scale, electrically insulating, bond strength greater than the bond strength between one of the plurality of thermoelectric elements and a barrier layer disposed on opposite ends of the thermoelectric element, and a thermal conductivity equal to or less than the thermal conductivity of one of the plurality of thermoelectric elements.

In yet another embodiment, the method includes soldering, melting or adhesively fixing the stress minimizing structural element to each of the pair of substrates.

### BRIEF DESCRIPTION OF THE DRAWINGS

FIG. 1 is a perspective view of one embodiment of the present invention showing the inclusion of a stress minimizing structural component.

FIG. 2 is a top plan view of the embodiment shown in FIG. 1 with the top thin film substrate removed showing various locations of the stress minimizing structural component.

FIG. 3 is a perspective view of another embodiment of the present invention showing a bar-shaped stress minimizing structural component.

FIG. 4 is a perspective view of another embodiment of the present invention showing the inclusion of at least two bar-shaped stress minimizing structural component.

FIG. 5 is a top plan view of the embodiment shown in FIG. 3 with the top thin film substrate removed showing various locations of the bar-shaped stress minimizing structural component.

FIGS. 6A-6F are top plan views of various positions for placing the structural elements in the present invention.

FIG. 7 is a cross-sectional view of a structural element of the present invention configured to the approximate size of the thermoelectric elements.

FIG. 8 is a cross-sectional view of another embodiment of the structural element of the present invention showing an elongated structural element or structural rail.

FIG. 9 is a cross-sectional view of the embodiment shown in FIG. 8 showing a portion of the electrically conductive layer removed.

### DETAILED DESCRIPTION OF THE PREFERRED EMBODIMENT

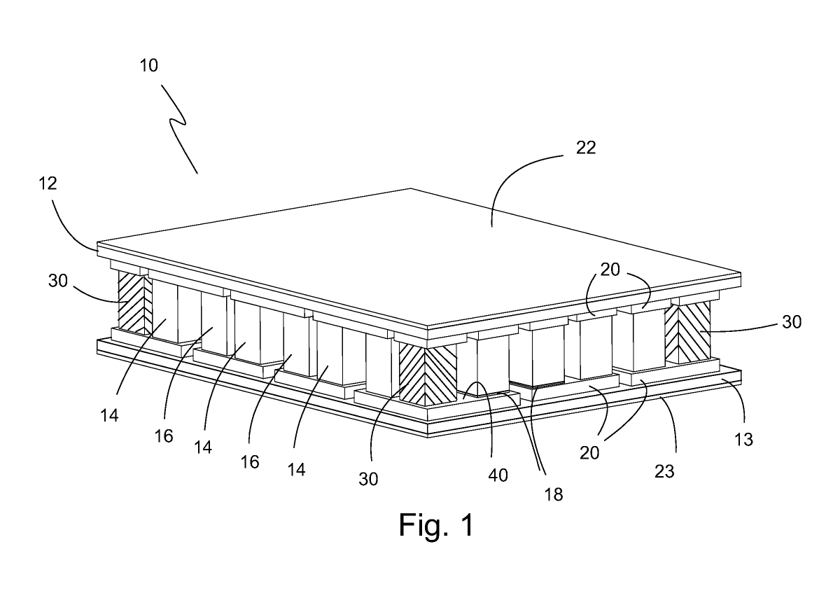

The preferred embodiment(s) of the present invention is illustrated in FIGS. 1-9. FIG. 1 is a perspective view of one embodiment of a thermoelectric device 10 according to the present invention. The basic structure of thermoelectric device 10 comprises P-type thermoelectric elements 14 and N-type thermoelectric elements 16 sandwiched between substrates 12 and 13. P-type thermoelectric elements 14 and N-type thermoelectric elements 16 are electrically connected in series and thermally connected in parallel through a plurality of electrically conductive pads 20 forming a thermoelectric element circuit to provide the Peltier effect, which is the technological basis for a working thermoelectric module. It is noted that the substrates may both be considered rigid substrates such as ceramic substrates or that only one side of thermoelectric device 10 may use the flexible substrate while the other side uses traditional substrates, i.e. ceramic (alumina), or that both opposed substrates are flexible substrates. When using only one flexible substrate, it is preferable to use the thin film substrate on the hot side of the thermoelectric module. The hot side tends to incur larger thermal stress due to the larger temperature difference that occurs during thermal cycling. The flexible substrate allows for expansion and contraction with much less restraint and stress because of its flexible nature. On the outside surface of flexible substrates 12 and 13 there is optionally disposed an electrically conductive layer 22 and 23, respectively, that is also thermally conductive and may also be solderable.

When substrates 12 and 13 are flexible substrates, the substrates are made of a flexible layer material. The flexible layer material provides electrical isolation from a heat source or heat sink while also functioning as a heat transfer medium. In particular, the material should have relatively high resistance to thermal cycling fatigue, low coefficient of thermal conductivity, relatively high dielectric strength, a broad operating temperature range, and relatively good heat transfer characteristics. The preferred material used in the present invention is a polyimide sheet material having a thickness of about 0.0005 inch (0.01 mm) to about 0.002 inch (0.051 mm). Other usable materials include flexible layer epoxies and materials that meet the particular specifications required for a given application. Although the thickness of the thin film material will enhance certain material characteristics at the expense of other material characteristics, the general criteria for selecting a preferred thickness for flexible layer substrates 12 and 13 is the material's tensile strength, its durability to withstand shear stress relative to the weight of the thermoelectric elements, its thermal conductivity, i.e. its ability to transfer heat, and its ability to withstand thermal stresses associated with thermal cycling of thermoelectric devices.

P-type thermoelectric elements 14 transfer heat in the direction of the current and N-type thermoelectric elements 16 transfer heat in the reverse direction of the current. By alternating P-type and N-type thermoelectric elements 14 and 16, hot and cold junctions are formed when electric current is provided to thermoelectric device 10. A heat exchanger (not shown) is thus configured so that heat may either be removed from, or added to, the heat exchanger by merely changing the direction of current flowing through thermoelectric device 10. Conversely, establishing a differential temperature across the thermoelectric device 10 will result in the generation of Direct Current at a level that is dependent on both the physical design of the module and the magnitude of the differential temperature. Thermoelectric materials most commonly used for making P-type thermoelectric elements 14 and N-type thermoelectric elements 16 are composed of, for example, a bismuth-tellurium alloy for the N-type elements and an antimony-tellurium alloy for the P-type elements.

Each distal end of P-type and N-type thermoelectric elements 14 and 16 may optionally be coated with a diffusion barrier 18. Diffusion barrier 18 prevents diffusion/migration of copper into P-type and N-type thermoelectric elements 14 and 16. Diffusion/migration of copper and other poisons such as, but not limited to, silver, gold and tin into the thermoelectric elements 14 and 16 shortens the working life of these components as thermoelectric elements, which may be acceptable in applications where the cost of the thermoelectric module is a determining factor. In these types of applications, diffusion barrier 18 is not required. Materials generally acceptable as diffusion barrier materials are, among others, nickel, or a titanium/tungsten mix, or molybdenum. The preferred material used in the present invention is nickel. The diffusion barrier also serves to make the surface of thermoelectric elements 14 and 16 solderable.

As disclosed above, substrates 12 and 13 are coated with, laminated with, or otherwise bonded on one or both planar surfaces of each substrate 12, 13 with a layer of an electrically conductive and preferably solderable and/or thermally conductive material forming electrically conductive layers 22 and 23 such as, for example, copper, aluminum, and the like. At least one side of each of the substrates 12 and 13 having the electrically conductive layers 22 and 23 are configured to form electrically conductive pads 20. The electrically conductive material may be formed over the entire planar surface of each side of substrates 12 and 13. For the sides of substrates 12, 13 that will be opposed and that sandwich thermoelectric elements 14, 16 therebetween, the electrically conductive material is then subsequently etched into the desired electrical connection pads 20 with the excess electrically-conductive material removed, or the desired connecting pad pattern may be coated, laminated or otherwise bonded to the planar surfaces of substrates 12 and 13 in the desired configuration.

Although P-type and N-type thermoelectric elements 14 and 16 are preferably soldered to the electrically conductive pads 20 in series forming a sandwiched matrix, other methods of bonding may be used. For example, electrically conductive epoxy is another form of electrically conductive material that may also be used to form the desired conductive pads connecting the P-type and N-type thermoelectric elements 14 and 16 in series. On the opposite surface of substrates 12 and 13, there may be the optional electrically conductive and preferably solderable planar layers 22 and 23 or layers 22, 23 may be configured to provide a mirror-image pattern of pads 20 of the electrically conductive material pads 20 to enhance thermal conductivity between thermoelectric device 10 and a surface with which thermoelectric device 10 is in contact. Alternately, thermally conductive epoxy or other thermally conductive adhesives may be used to form layers 22, 23 or the desired pads 20 on the outside surfaces of substrates 12 and 13.

One or more electrically non-conductive stress minimizing structural elements 30 are positioned between opposed electrically conductive pads 20 or directly between the substrates 12 and 13. In one embodiment, the stress minimizing structural element 30 replaces one of a P-type or N-type thermoelectric element 14 and 16. Because stress minimizing structural element 30 is electrically non-conductive, an electrically conductive link 40 is required between adjacent electrically conductive pads 20 to maintain the electrically conductive serial link between adjacent P-type and N-type thermoelectric elements 14, 16. Electrically conductive link 40 may be a separate component electrically connecting adjacent electrically conductive pads 20 or may be an electrically conductive pad 20 that is longer incorporating conductive link 40. Stress minimizing structural element 30 in this embodiment is also called a stress minimizing structural post 30. The desired property of the stress minimizing structural post 30 is a low thermal conductivity since it will connect the hot and cold sides of module 10. If stress minimizing structural element 30 has a high thermal conductivity, the high thermal conductivity would create an undesirable thermal “short.” A low coefficient of thermal expansion is also desirable to limit the contribution of movement to the components to which it is attached. It is further desirable that the material in the stress minimizing structural element 30 also possesses a processing temperature above 260° C., a hot operating temperature of at least 100° C. and a cold operating temperature of −20° C. or below. Additionally, the stress minimizing structural element 30 should have a comparatively high tensile and compressive strength to ensure that element 30 will not break. The material preferably has a high modulus of elasticity to prevent movement due to thermal or physical stress and preferably has a high bond strength between substrates 12, 13 and element 30 to limit movement without failing.

One method of attaching stress minimizing structural element 30 is to solder element 30 on individual electrically conductive pads 20 incorporated just for element 30. These are created in the same manner as the electrically conductive pads 20 for thermoelectric elements 14, 16. It should be understood that in order to solder element 30 to electrically conductive pads 20 requires that the ends of non-electrically conductive element 30 must be metalized to facilitate soldering. Another method is to utilize an enlarged electrically conductive pad 20 (that is a combination of adjacent electrically conductive pads 20 and electrically conductive links 40) on one side with an individual pad 20 on the opposed side. Yet another method includes using a material that is bondable to substrate 12 or 13 without solder. The post material may be comprised of one type of material or a plurality of layers of several materials that provide a substantial number of the preferred characteristics and/or properties disclosed above. Stress minimizing structural element 30 may occupy one location in an array of thermoelectric elements 14, 16 or be placed outside of the array. The preferred material for stress minimizing structural element 30 is polyimide, however, other materials such as epoxies, plastic, ceramic, and the like may be used, especially when low temperature solder is used to bond thermoelectric elements 14, 16 to electrically conductive pads 20. To bond stress minimizing structural element 30 to electrically conductive pad 20, soldering is one method previously disclosed but adhesives capable of providing and maintaining their adhesive properties over the operating temperature range of thermoelectric module 10 may also be used.

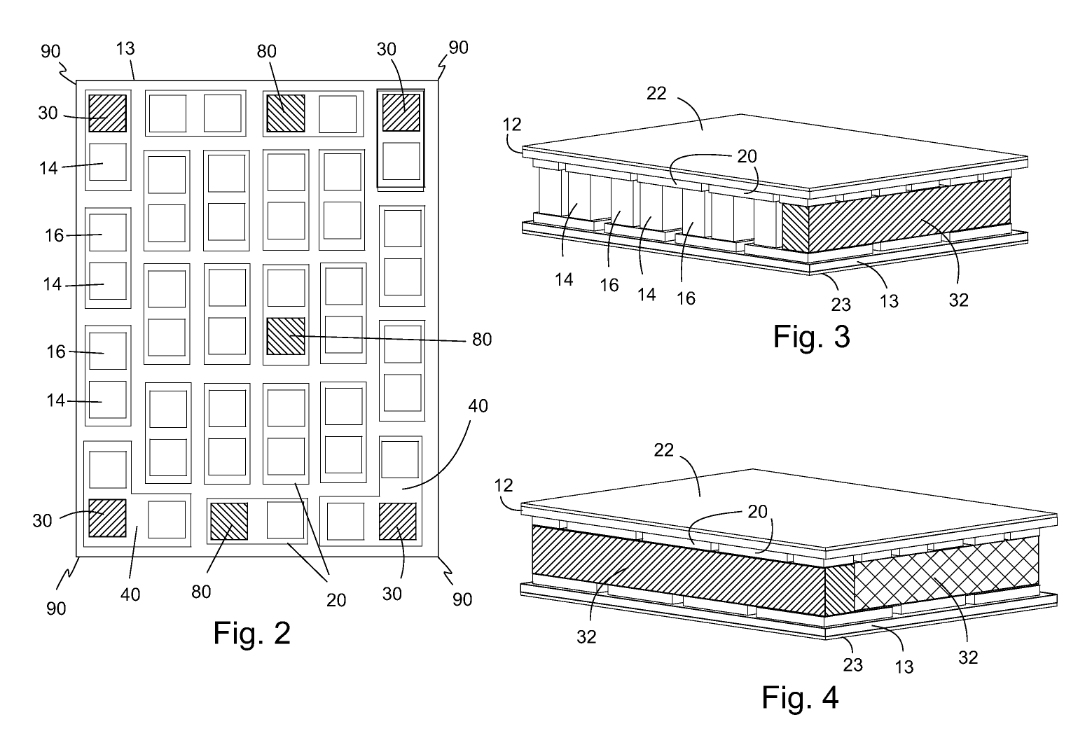

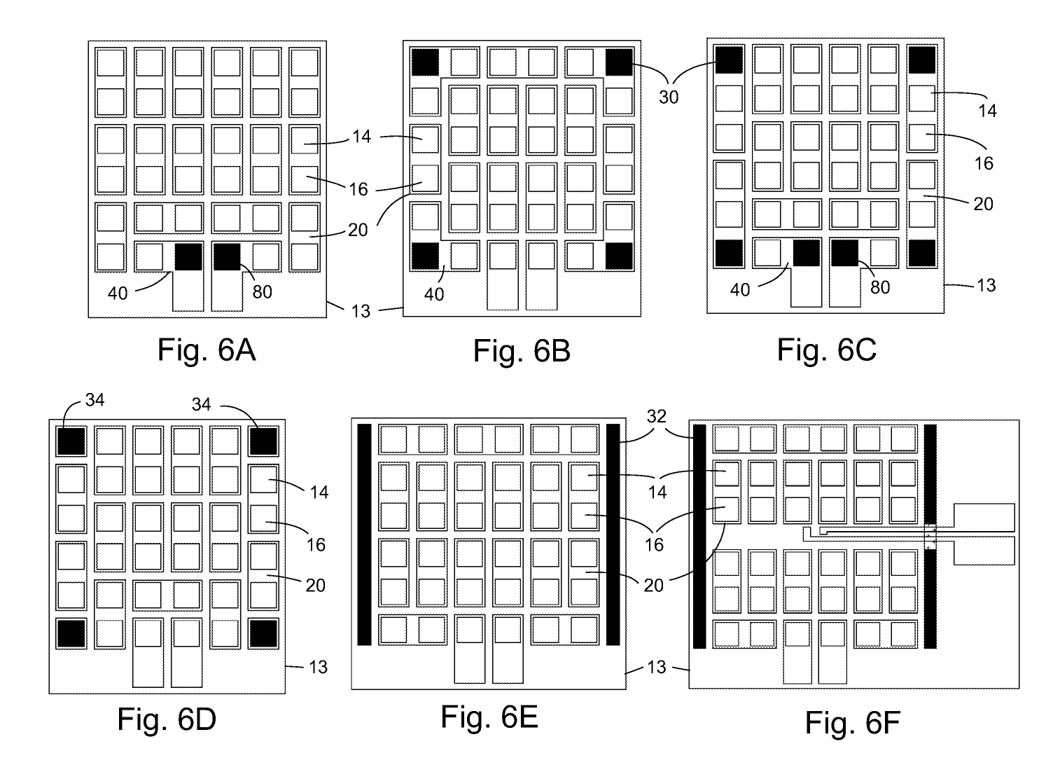

Turning now to FIG. 2, there is illustrated and shown possible locations for situating stress minimizing structural element 30. FIG. 2 is a top plan view with the top substrate 12 and conductive pads 20 removed for clarity. In this embodiment, stress minimizing structural element 30 is positioned at the corners 90 of thermoelectric module 10. As can be seen in some situations, the electrically conductive pad 20 includes electrically conductive link 40 to provide and electrical pathway to the next, adjacent thermoelectric element 14 and/or 16, depending on the arrangement of the thermoelectric element array. It should be understood that other locations 80 may be used for placement of stress minimizing structural element 30 and that, if used, additional electrically conductive links 40 will be required to maintain electrical connectivity between adjacent thermoelectric elements 14, 16. FIGS. 6A-6F described below provide further examples of locations for stress minimizing structural elements 30.

FIG. 3 illustrates another embodiment of the present invention where the stress minimizing structural element 30 is configured as a bar and identified as stress minimizing structural element 32. It should be understood that electrically conductive link 40 will be required to maintain electrical connectivity between adjacent thermoelectric elements 14, 16 when element 32 is used between electrically conductive pads 20 or element 32 must be configured to be electrically conductive. In this embodiment, stress minimizing structural element 32 is positioned along a side or a portion of a side between the substrates 12, 13 of thermoelectric module 10. Depending on the configuration of the thermoelectric element array, a plurality of electrically conducting links 40 may be required to maintain the serial electrical connectivity of thermoelectric elements 14, 16. FIG. 4 illustrates still another embodiment of the present invention where stress minimizing structural element 32 is disposed on two sides of thermoelectric module 10. In this case, care must be taken so that structural element 32 along one side and structural element 32 along a transverse side do not short circuit the thermoelectric element array if the structural elements are electrically conductive and, if not electrically conductive, then electrically conducting links 40 need to be properly located and incorporated into thermoelectric module 10 to maintain electrical continuity between thermoelectric elements 14, 16 of the module.

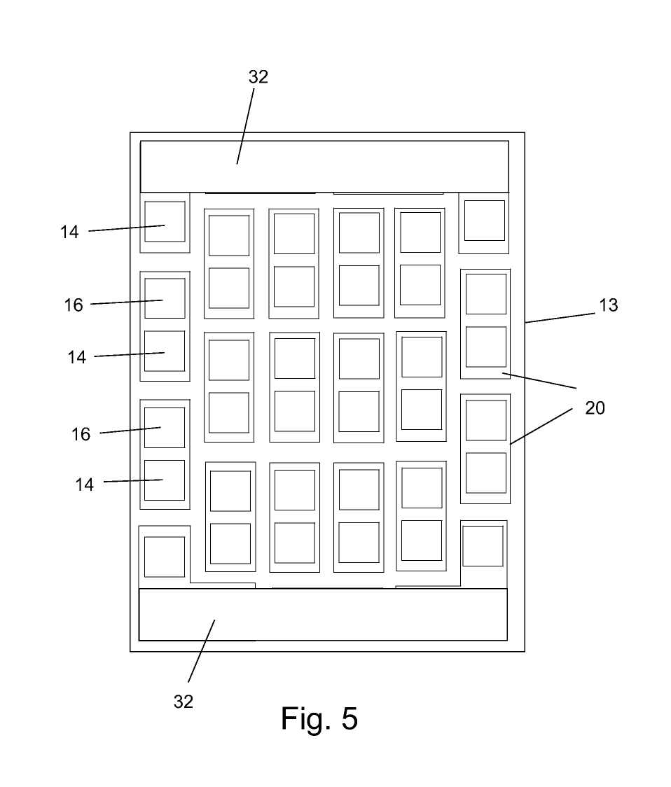

FIG. 5 is a top plan view of another embodiment of the present invention where stress minimizing structural element 32 is disposed along opposite sides of thermoelectric module 10. As disclosed above, a plurality of electrically conducting links 40 will be required to maintain the serial electrical connectivity of thermoelectric elements 14, 16 in order to route the electrical circuit around the “posts” or stress minimizing structural element 32.

It is also contemplated, as previously disclosed, that the stress minimizing structural element 30 and/or stress minimizing structural element 32 are positioned between substrates 12, 13 but adjacent and/or surrounding but separate from the thermoelectric element array, or located in strategic locations of thermoelectric module 10 that tend to experience the higher levels of thermal and/or physical (both mechanical and manual) stress during handling and/or use.

Turning now to FIGS. 6A-6F, there is shown other examples of variations in type and use of stress minimizing structural elements 30. Examples of positioning of structural elements show how and/or where they can be positioned in the desired locations. This includes at the lead tabs only, at the corners only, at lead tabs and corners, and outside of the array of thermoelectric elements. It also shows how the stress minimizing structural elements 30 can be placed on pads shared by a thermoelectric element or on individual pads. Furthermore, if an elongated structural element is desired, the figures show how the elongated structural element can be altered to allow traces from secondary components to pass beneath the structural element by removing the electrically-conductive layers and possibly some of the dielectric material of the structural element body to allow clearance of electrically conductive traces below the structural element.

In these cases, pads are needed to solder the structural elements into position. If an appropriate adhesive is found, however, the structural elements may be adhered between the dielectric layers of the module substrates 12, 13 and not require a copper pad in the correct position, avoiding the use of a laminate if the copper layer is not required. Further, if a plastic with appropriate properties is identified, the plastic may be heated into a softened state to bond with the module dielectric, ceramic, plastic, or epoxy as long as the material is strong under operating conditions and meets the other preferred criteria disclosed above. In the case where a copper layer is not required, the structural element would preferably have a greater thickness to compensate for the lack of copper pads.

FIG. 6A illustrates the use of stress minimizing structural elements 30 on the electrical lead pads incorporated using circuit pads 20, 40 of module 10. FIG. 6B illustrates the use of stress minimizing structural elements 30 at corner positions of module 10. FIG. 6C illustrates the use of stress minimizing structural elements 30 on the electrical lead pads and the corner pads of module 10. FIG. 6D illustrates the use of stress minimizing structural elements 30 at corner positions outside of the thermoelectric element circuit pattern. FIG. 6E illustrates the use of elongated stress minimizing structural elements 30 along opposite sides and outside of the thermoelectric circuit pattern. FIG. 6F illustrates the use of elongated stress minimizing structural elements 30 along opposite sides and outside of the thermoelectric circuit pattern to accommodate additional components. This is accomplished by either placing the stress minimizing structural elements 30 to provide a space between adjacent structural elements 30 to accommodate electrically-conductive circuit traces or by removing electrically conductive material from a portion of one side of the stress minimizing structural elements 30.

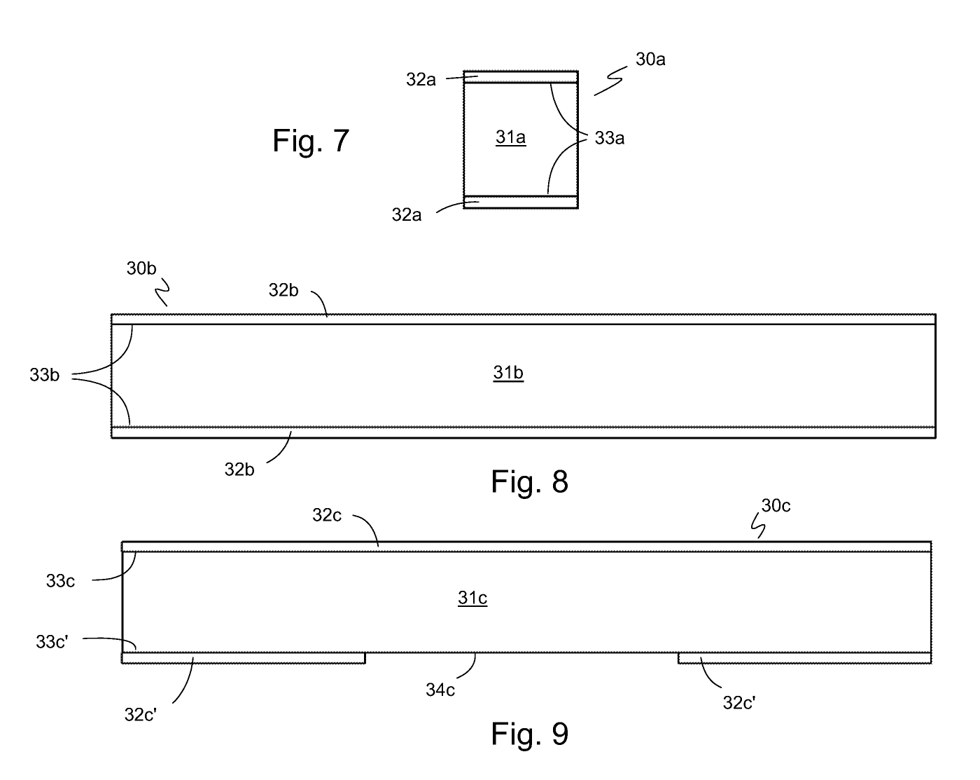

Turning now to FIG. 7, there is illustrated one embodiment of a stress minimizing structural element 30. In this embodiment, structural element 30a is approximately the size of and cross-sectional shape of the thermoelectric element 14, 16. Structural element 30a includes a structural element body 31 a and a coating of electrically-conductive material 32a on opposite ends 33a of structural element body 31a.

FIG. 8 illustrates another embodiment of a stress minimizing structural element 30. In this embodiment, structural element 30b is in the shape of an elongated bar. Structural element 30b includes an elongated structural element body 31 b and a coating of electrically-conductive material 32b along opposite, longitudinal sides 33b of elongated structural element body 31b.

FIG. 9 illustrates another embodiment of stress minimizing structural element 30. In this embodiment, structural element 30c is in the shape of an elongated bar. Structural element 30c includes an elongated structural element body 31c, a single, continuous coating 32c of electrically-conductive material along one longitudinal side 33c and two separated coatings 32c′ of electrically-conductive material along one longitudinal side 33c′ forming a portion 34c of longitudinal side 33c′ having no electrically-conductive material. The elongated structural elements 30c are capable of spanning a greater distance and the structural element 30 that is the approximate size of the thermoelectric elements 14, 16. Furthermore, longitudinal side 33c′ with the portion 34c permits electrically-conductive traces to pass under or over (depending on the use and orientation of structural element 30c) the structural element 30.

There are many advantages of using structural elements 30. Structural elements 30 may be used to reduce physically or thermally induced stresses experienced by thermoelectric elements of thermoelectric element arrays by positioning them to resist the transmission of the stress forces. One aspect is to position the structural elements 30 adjacent to areas that are subjected to physical deformation during handling such as the addition of leads or at points where thermally induced stresses are greatest. The stiffness of the material and the greater bond strength of the structural element 30 resist the deformation of the module under the above-described conditions and prevent the stress-induced forces from being realized on the internal thermoelectric elements 14, 16.

Additionally, the structural elements 30 of the preferred method may be soldered into place at the same time that the thermoelectric module is fabricated resulting in reduced yield loss in secondary operations as well as eliminating a separate secondary operation to add the structural element 30.

Structural elements 30 are generally placed as necessary to minimize the amount of compressive forces, tensile stress, and shear stress. Structural elements 30 may also be in strategic locations to enable the fabrication of a circular module with integrated or attached heat sinks that are rotated forming a fan, blower, or other fluid pumping device with active heat pumping.

Another advantage is that the structural element 30 may be in the form of a perimeter seal providing a barrier for contaminants that requires very little or minimal alternate sealing at the point of the electrical supply. It is contemplated that structural element 30 may be a single, unitary structure or a plurality of rails or bars that connect to adjacent rails or bars to provide the perimeter seal.

Although the preferred embodiments of the present invention have been described herein, the above description is merely illustrative. Further modification of the invention herein disclosed will occur to those skilled in the respective arts and all such modifications are deemed to be within the scope of the invention as defined by the appended claims.

What is claimed is:

1. A thermoelectric module capable of minimizing thermally and physically induced stress, the module comprising:
a pair of substrates having a plurality of electrically conductive pads disposed on opposing faces;
a plurality of P-type and N-type thermoelectric elements interposed between the pair of substrates, each of the plurality of conductive pads connecting adjacent P-type and N-type thermoelectric elements to each other in series forming a thermoelectric element circuit; and
one or more of a stress minimizing structural element interposed between the pair of substrates wherein the stress minimizing structural element has a first surface fixed to one of the pair of substrates and a second surface fixed to the other of the pair of substrates in a location between the pair of substrates that minimize the effects of physical and thermal stresses on the plurality of P-type and N-type thermoelectric elements.

2. The module of claim 1 wherein the stress minimizing structural element is incorporated into the thermoelectric element circuit where a predefined thermoelectric element in the thermoelectric element circuit is replaced by the stress minimizing structural element, the stress minimizing structural element being electrically conductive or the electrically conductive pad has a pad surface area sufficient to accommodate the P-type and N-type thermoelectric elements and the stress minimizing structural element.

3. The module of claim 1 wherein the stress minimizing structural element is incorporated outside of the thermoelectric element circuit.

4. The module of claim 1 wherein the stress minimizing structural element is made of a material selected from the group consisting of epoxy, plastic, ceramic, metal, and composite.

5. The module of claim 4 wherein the composite is a glass-filled thermoplastic.

6. The module of claim 5 wherein the glass-filled thermoplastic is a glass-filled polyimide.

7. The module of claim 1 wherein the stress minimizing structural element is a laminate.

8. The module of claim 7 wherein the laminate includes a structural element body having a metal coating on one of opposite ends of the structural element body or opposite longitudinal sides of the structural element body.

9. The module of claim 8 wherein the metal coating is copper.

10. The module of claim 1 wherein the stress minimizing structural element is made of material having at least one characteristic selected from the group consisting of low thermal conductivity on a thermal conductivity scale, electrically insulating, bond strength greater than the bond strength between one of the plurality of thermoelectric elements and a barrier layer disposed on opposite ends of the thermoelectric element, and a thermal conductivity equal to or less than the thermal conductivity of one of the plurality of thermoelectric elements.

11. The module of claim 1 wherein the stress minimizing structural element is attached to each of the pair of substrates by being soldered, melted or adhesively fixed into position.

12. A method of making a thermoelectric module capable of minimizing thermally and physically induced stress, the method comprising:
obtaining a pair of substrates having a plurality of electrically conductive pads disposed on opposing faces;
electrically connecting a plurality of P-type and N-type thermoelectric elements between opposing sides of the pair of substrates having the plurality of electrical pads wherein each of the plurality of electrical pads connects adjacent P-type and N-type elements to each other in series forming a thermoelectric element circuit; and
securing one or more of a stress minimizing structural element between the pair of substrates wherein the stress minimizing structural element has a first surface fixed to one of the pair of substrates and a second surface fixed to the other of the pair of substrates in a location between the pair of substrates that minimize the effects of physical and thermal stresses on the plurality of P-type and N-type thermoelectric elements.

13. The method of claim 12 wherein the securing step includes incorporating the stress minimizing structural element into the thermoelectric element circuit where a predefined thermoelectric element in the thermoelectric element circuit is replaced by the stress minimizing structural element, the stress minimizing structural element being electrically conductive or the electrically conductive contact has a contact surface area sufficient to accommodate the P-type and N-type thermoelectric elements and the stress minimizing structural element.

14. The method of claim 12 wherein the securing step includes incorporating the stress minimizing structural element outside of the thermoelectric element circuit.

15. The method of claim 12 further comprising forming the stress minimizing structural element from a material selected from the group consisting of epoxy, plastic, ceramic, metal, and composite.

16. The method of claim 12 further comprising forming the stress minimizing structural element from a glass-filled thermoplastic.

17. The method of claim 12 further comprising forming the stress minimizing structural element having a structural element body with a metal coating on one of opposite ends of the structural element body or one of opposite longitudinal sides of the structural element body.

18. The method of claim 12 further comprising forming the stress minimizing structural element from a material having at least one characteristic selected from the group consisting of low thermal conductivity on a thermal conductivity scale, electrically insulating, bond strength greater than the bond strength between one of the plurality of thermoelectric elements and a barrier layer disposed on opposite ends of the thermoelectric element, and a thermal conductivity equal to or less than the thermal conductivity of one of the plurality of thermoelectric elements.

19. The method of claim 12 wherein the securing step includes one of soldering, melting or adhesively fixing the stress minimizing structural element to each of the pair of substrates.

20. A thermoelectric module having a pair of substrates with a plurality of electrically conductive pads disposed on opposing faces and a plurality of P-type and N-type thermoelectric elements electrically connected to the conductive pads between the pair of substrates forming a thermoelectric element circuit, the improvement comprising:
one or more of a stress minimizing structural element interposed between the pair of substrates wherein the one or more stress minimizing structural element has a first surface fixed to one of the pair of substrates and a second surface fixed to the other of the pair of substrates in a location between the pair of substrates that minimize the effects of physical and thermal stresses on the plurality of P-type and N-type thermoelectric elements.
